(19) United States
(12) Patent Application Publication
(10) Pub. No.: US 2018/0352955 A1
(43) Pub. Date: Dec. 13, 2018

(54) ADJUSTABLE MOUNT FOR A MONITOR

(71) Applicant: Middle Atlantic Products, Inc., Fairfield, NJ (US)

(72) Inventors: Nico Corbo, Blairstown, NJ (US); Leszek Markowski, Riverdale, NJ (US)

(21) Appl. No.: 16/001,692

(22) Filed: Jun. 6, 2018

Related U.S. Application Data
(60) Provisional application No. 62/516,953, filed on Jun. 8, 2017.

(51) Int. Cl. A47B 97/00; F16M 13/02; H05K 5/02

(52) U.S. Cl. CPC A47B 97/001; F16M 13/027; F16M 2200/024; H05K 5/0234; F16M 13/022

(57) ABSTRACT

An adjustable mount for a TV or video monitor is disclosed which includes a fixed bracket having two side walls, each with a sloped front edge, a top end and a bottom end. A mounting notch is formed in each of the side walls. At least one adjustable bracket is removably mounted on the fixed bracket and includes a front panel with an outer surface. Two side panels are attached to the front panel and extend away from the outer surface. The side panels are spaced apart from one another and located adjacent to the side walls of the fixed bracket. A crossbar extends between the side panels and is rotatable within the notches of the fixed bracket. The rotation of the crossbar causes the adjustable bracket to pivot relative to the fixed bracket varying the angle of the front panel plane relative to the fixed bracket.

### RELATED APPLICATION

This application is related to and claims priority from U.S. Provisional Application No. 62/516,953, filed on Jun. 8, 2017, the disclosure of which is incorporated herein by reference in its entirety.

### BACKGROUND

There has been an increase in recent year in use of flat screen televisions and monitors in many day-to-day uses. Various mounting mechanisms have been developed to provide easy adjustment for such flat screens monitors. However, most mounting mechanisms involve complicate linkage systems to provide multi-degree movement.

While existing systems are useful in providing adjustable orientation for displays, they are somewhat complex and costly. Thus, a need exists for relatively less complex monitor mount that provides angular adjustment for a monitor.

### SUMMARY OF THE INVENTION

The present invention relates to an adjustable mount for a TV or video monitor. The mount includes a fixed bracket having two side walls that each have a sloped front edge, a top end and a bottom end. A mounting notch is formed in the top end of each of the side walls adjacent to the sloped front edge. The fixed bracket has an axis extending between and parallel to the side walls.

The mount also includes at least one adjustable bracket that is removably mounted on the fixed bracket. The adjustable bracket includes a front panel with an outer surface lying along a plane. The plane defines an angle relative to the axis of the fixed bracket. Two side panels are attached to the front panel and extend away from the outer surface. The side panels are spaced apart from one another a sufficient distance and located adjacent to and outside of the side walls of the fixed bracket when the adjustable bracket is mounted to the fixed bracket. A crossbar extends between and is attached to the side panels adjacent to a top end of the side panels. The crossbar is seated and rotatable within the notches of the side walls of the fixed bracket. The rotation of the crossbar in the notches causes the adjustable bracket to pivot relative to the fixed bracket so as to vary the angle of the front panel plane relative to the axis of the fixed bracket. The sloping front edges of the fixed bracket side walls facilitate the amount of pivoting.

The side walls of the fixed bracket are preferably connected to one another by a top wall and may be attached to a ceiling support.

In one embodiment, there are two front sloped edges on opposite sides of each side wall. The front edges sloping downward and inward toward one another. In this embodiment there are two notches on the top end of each side wall, one notch adjacent to each front edge.

In one embodiment, the angle of the front panel plane is adjustable in a range from about substantially zero degrees to at least about 20 degrees relative to the axis of the fixed bracket.

The mount may include a locking mechanism to lock the angular orientation of the adjustable bracket relative to the fixed bracket. The locking mechanism may include a curved slot formed in at least one side panel of the adjustable bracket that is aligned with a threaded hole in the side wall of the fixed bracket, and a locking bolt removable inserted through the slot and threaded into the hole.

Alternately or in addition the locking mechanism may include an incremental adjustment mechanism with a series of adjustment holes formed in at least one side panel at predetermined positions so as to provide incremental angular adjustments. A pin hole is formed in the side wall of the fixed bracket that is aligned with the adjustment holes. A removable bolt or pin inserted through one adjustment hole into the pin hole to lock the adjustable bracket in a desired orientation. The pin may be spring loaded and attached to the adjustable bracket and biased into engagement with the holes to permit easy disengagement by pulling the pin out of engagement with the pin hole. The adjustment holes are preferably spaced apart from one another a sufficient distance to provide five degree changes in angular orientation of the front panel plane relative to the axis of the fixed bracket.

An adapter angle may be attached to the front panel with a channel section that include spaced apart legs. An extrusion may be removably attached to the adapter angle, the extrusion having spaced apart slots that are configured to engage with and slide upon the legs of the adapter angle.

The fixed bracket may include a mounting flange that is located between and attached to the side walls, the mounting flange including one or more holes for securing the fixed bracket to the wall.

The foregoing and other features of the invention and advantages of the present invention will become more apparent in light of the following detailed description of the preferred embodiments, as illustrated in the accompanying figures. As will be realized, the invention is capable of modifications in various respects, all without departing from the invention. Accordingly, the drawings and the description are to be regarded as illustrative in nature, and not as restrictive.

### BRIEF DESCRIPTION OF THE DRAWINGS

For the purpose of illustrating the invention, the drawings show a form of the invention which is presently preferred. However, it should be understood that this invention is not limited to the precise arrangements and instrumentalities shown in the drawings.

FIG. 1 is a perspective view of an adjustable mount for securing one or more monitors to a ceiling.

FIG. 2 is a perspective view of an adjustable bracket of the mount of FIG. 1.

FIG. 3 is a side view of the mount of FIG. 1 illustrating two angular positions for the adjustable bracket.

FIG. 4 is a partial view of the mount as shown in FIG. 6.

FIG. 5 is a side view of an embodiment of the mount of FIG. 1 with a monitor mount attached to one adjustable bracket and a second adjustable bracket shown disengaged.

FIG. 6 is a side view of an embodiment of the mount of FIG. 5 with the second adjustable bracket shown mounted to the fixed bracket.

FIG. 7 is a perspective view of a ceiling mounted monitor assembly with multiple mounts for supporting extrusions and with monitor mounts shown attached to the extrusions.

FIG. 8 is a perspective view of another embodiment of an adjustable mount for securing one or more monitors to a wall.

FIG. 9 is a side view of the mount of FIG. 8 illustrating an angular position of the adjustable bracket.

FIG. 10 is a side view of the mount of FIG. 8 with a monitor mount shown attached to the adjustable bracket, with the adjustable bracket disengaged from the fixed bracket.

FIG. 11 is a side view of the mount of FIG. 10 with the adjustable bracket shown mounted to the fixed bracket.

FIG. 12 is a perspective view of a wall mounted monitor assembly with multiple wall mounts for supporting an extrusion and with monitor mounts shown attached to the extrusion.

### DESCRIPTION OF THE EMBODIMENTS

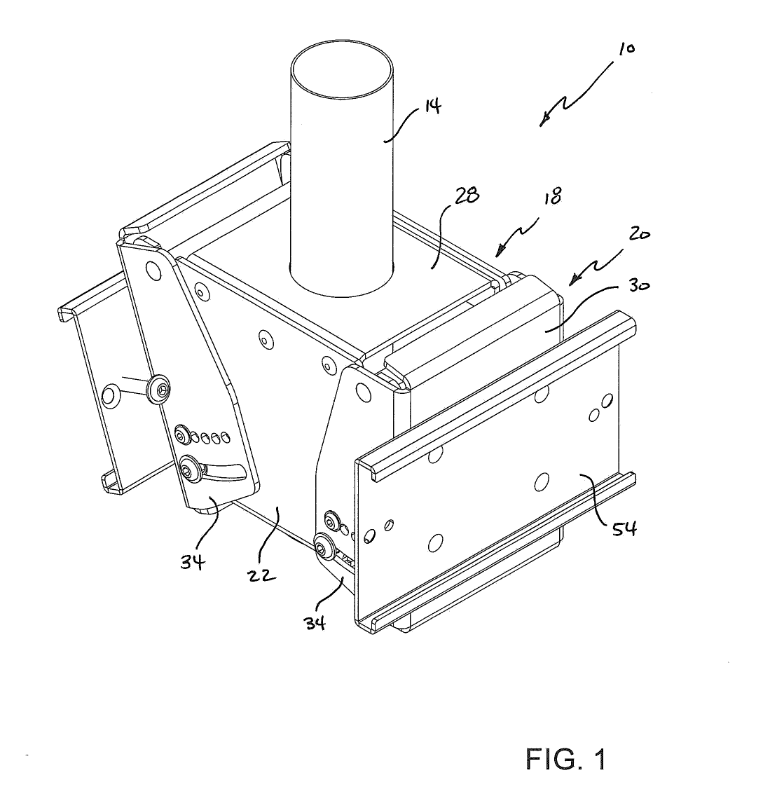

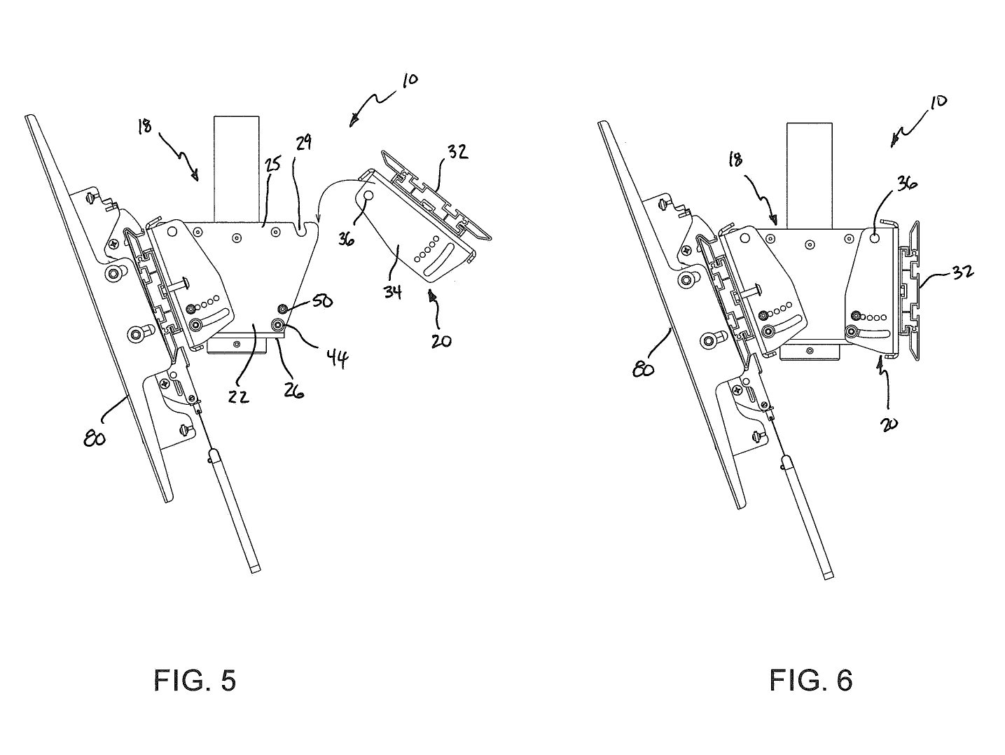

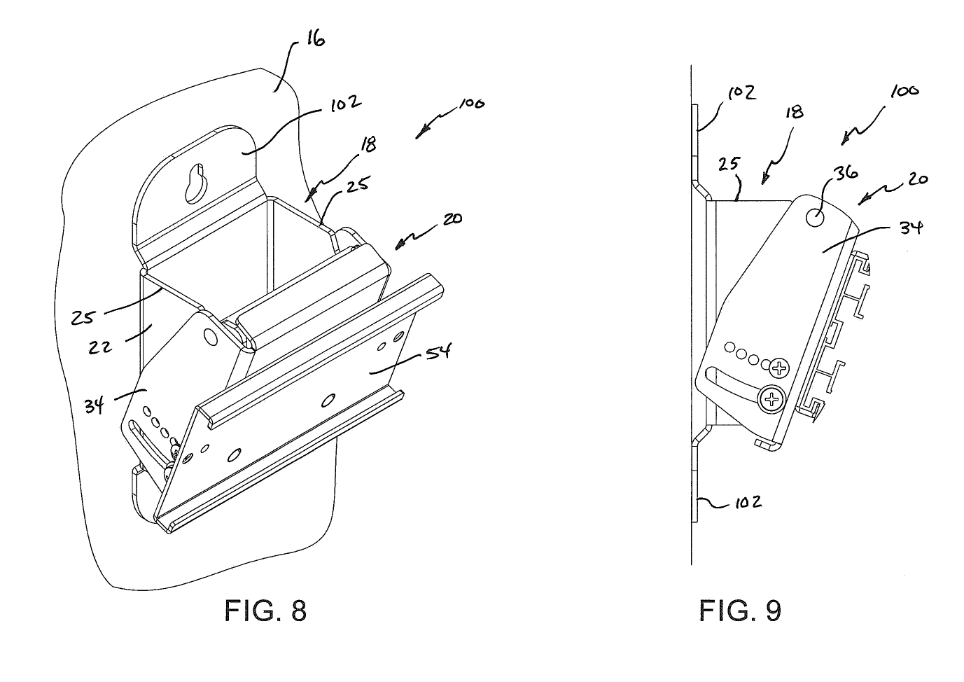

Referring to the figures, embodiments of a mount 10 are shown. The mount 10 is configured to attach or mount to a monitor (not shown). In the embodiment of the invention shown in FIG. 1, the mount 10 is configured to attach to a ceiling support 14 or directly to a wall 16 (FIG. 8). The mount 10 includes a fixed bracket 18 and at least one adjustable bracket 20. The fixed bracket 18 includes two side walls 22 that each have a sloped front edge 24, a top end 25 and a bottom end 26. The side walls 22 may be connected to one another by a top wall 28 (see, FIG. 5). A mounting slot or notch 29 is formed in the top end 25 of each of the side walls 22 adjacent to the sloped front edge 24. In the ceiling mounted version shown in FIG. 1, the side walls 22 are attached to the ceiling support 14 and there are preferably two front sloped edges 24 on opposite sides of each side wall 22, the front edges 24 sloping downward and inward toward one another. Also in this embodiment, each side wall 22 includes two slots or notches 29 on the top end 25, one notch adjacent to each front edge 24.

The adjustable bracket 20 is removably mountable on the fixed bracket 18. The adjustable bracket 20 includes a front panel or end 30 onto which an extrusion 32 is attachable and that provides an interface for a conventional monitor mount or a monitor. The adjustable bracket 20 includes two side panels 34 that are attached to the front panel 30 and extend away from the surface of the front panel where the extrusion 32 is attached. The side panels 34 are spaced apart from one another a sufficient distance so as to be located adjacent to and outside of the side walls 22 of the fixed bracket 18 when the adjustable bracket 20 is mounted to the fixed bracket 18. A crossbar 36 extends between and is attached to the side panels 34 adjacent to a top end of the side panels 34. The crossbar 36 is sized to slide into the notch 29, permitting the adjustable bracket 20 to pivot about the notch 29 and, thus, relative to the fixed bracket 18.

As noted above, the front edges 24 of the fixed bracket side walls 22 are sloped or tapered inward. This allows for the adjustable bracket 20 to pivot through a range of angles, thus permitting the front panel 30 to lie along a plane that is oriented from at least substantially vertical to at least about 20 degrees or more relative to vertical. As should be apparent, this allows for various angular orientations of monitors that are attached to the mount 10.

Referring to FIG. 3, a locking mechanism 40 is provided to lock the angular orientation of the adjustable bracket 20 relative to the fixed bracket 18. In one embodiment, a curved slot 42 is provided in at least one side panel 34 that lines up with a threaded hole 44 in the side wall 22 of the fixed bracket 18. When the adjustable bracket 20 is pivoted to the desired angular position, a locking bolt 46 is inserted through the slot and threaded into the hole 44 and tightened to lock the orientation.

This locking mechanism 40 allows for a wide variety of angular adjustments. It is also contemplated that the locking mechanism 40 can include, either alternately or in addition, an incremental adjustment mechanism. For example a series of adjustment holes 48 could be formed in at least one side panel 34. The adjustment holes 48 could be formed at predetermined positions so as to permit, for example, 5 degree incremental angular adjustments. A pin or threaded hole 50 is formed in the side wall 22 of the fixed bracket 18 that lines up with the adjustment holes 48. When the adjustable bracket 20 is pivoted to the desired angular position, a bolt or pin 52 is inserted through the appropriate adjustment hole 48 into the pin hole 50, thus locking the adjustable bracket 20 in the desired orientation. To permit toolless locking, the bolts/pins 52, can be replaced by a spring loaded pin that is attached to the adjustable bracket 20 or the fixed bracket and is biased into engagement with the holes/slots and permits easy disengagement by pulling the pin out of engagement with the pin hole 50.

In the illustrated embodiment, in order to attach the extrusion 32 to the adjustable bracket 20, an adapter angle 54 is attached to the front panel 30. The adapter angle 54 engages with mating slots 56 in the back of the extrusion 32. The adapter angle 54 is preferably a channel section with upper and lower legs 54A, 54B that engage with the mating slots 56 (see, FIG. 4).

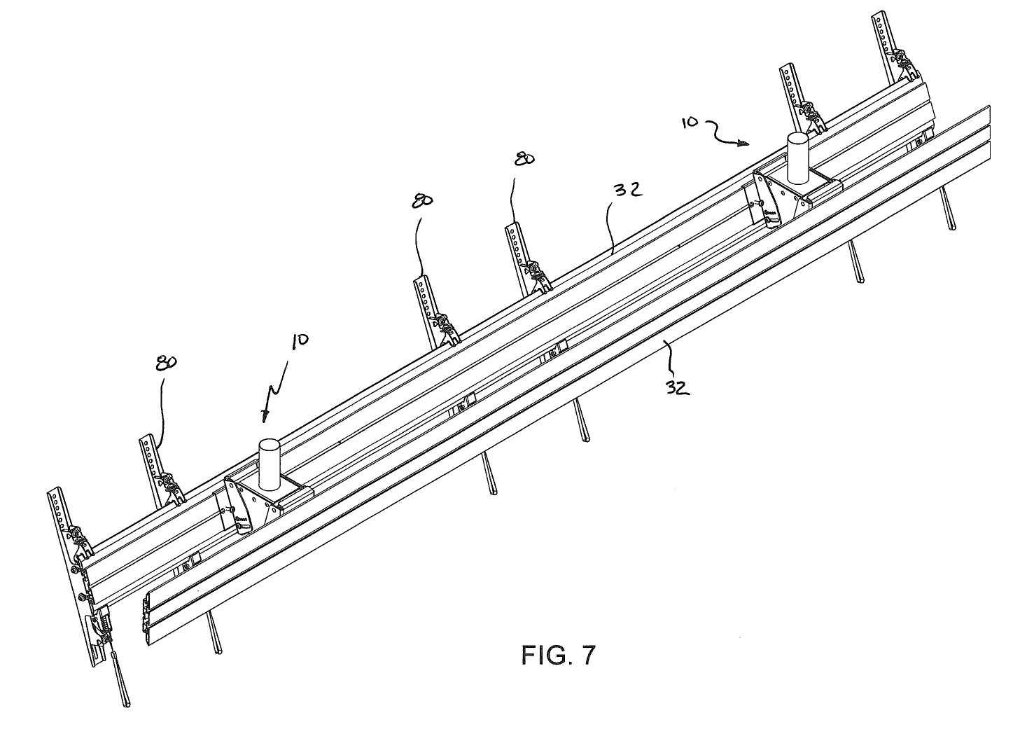

In the ceiling mounted embodiment of FIG. 7, multiple mounts 10 are attached to the ceiling with a common extrusion 32 extending from one mount 10 to the other. The monitor mounts 80 that attach to the monitors (not shown) can then be attached to the extrusion 32 in a conventional manner as shown. This embodiment of the invention is particularly useful for mounting a plurality of monitors from a ceiling.

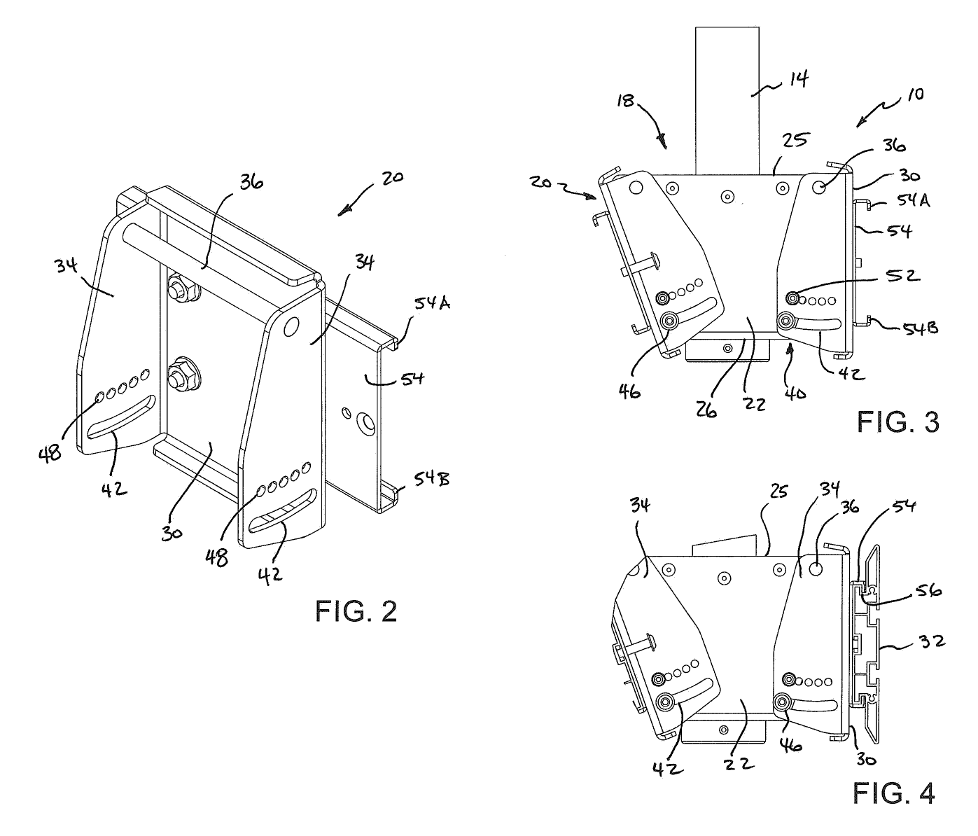

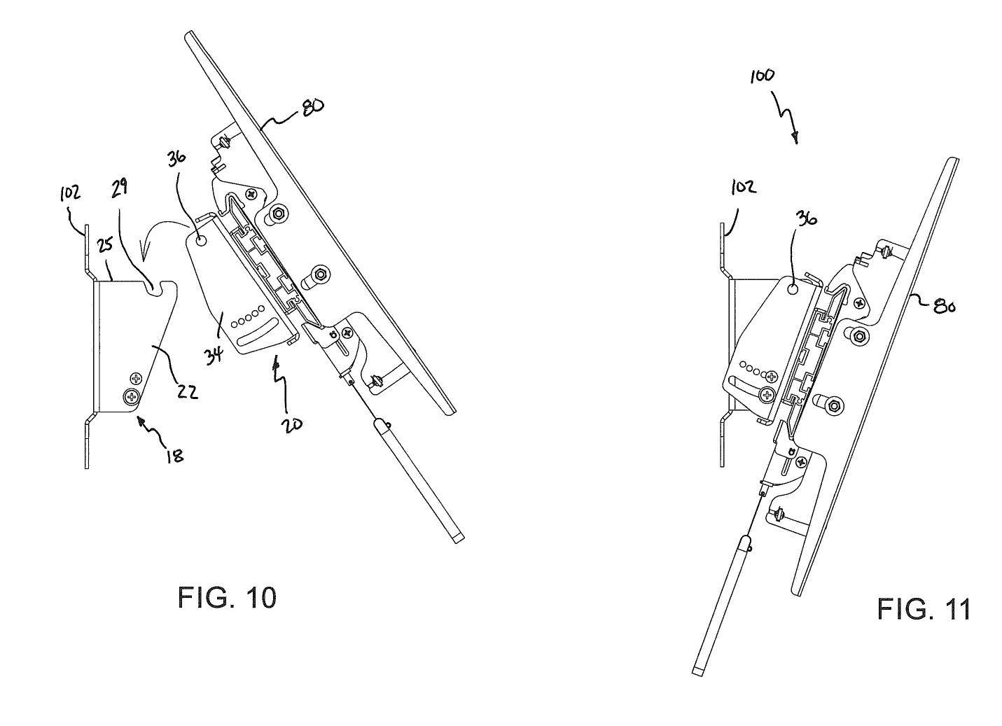

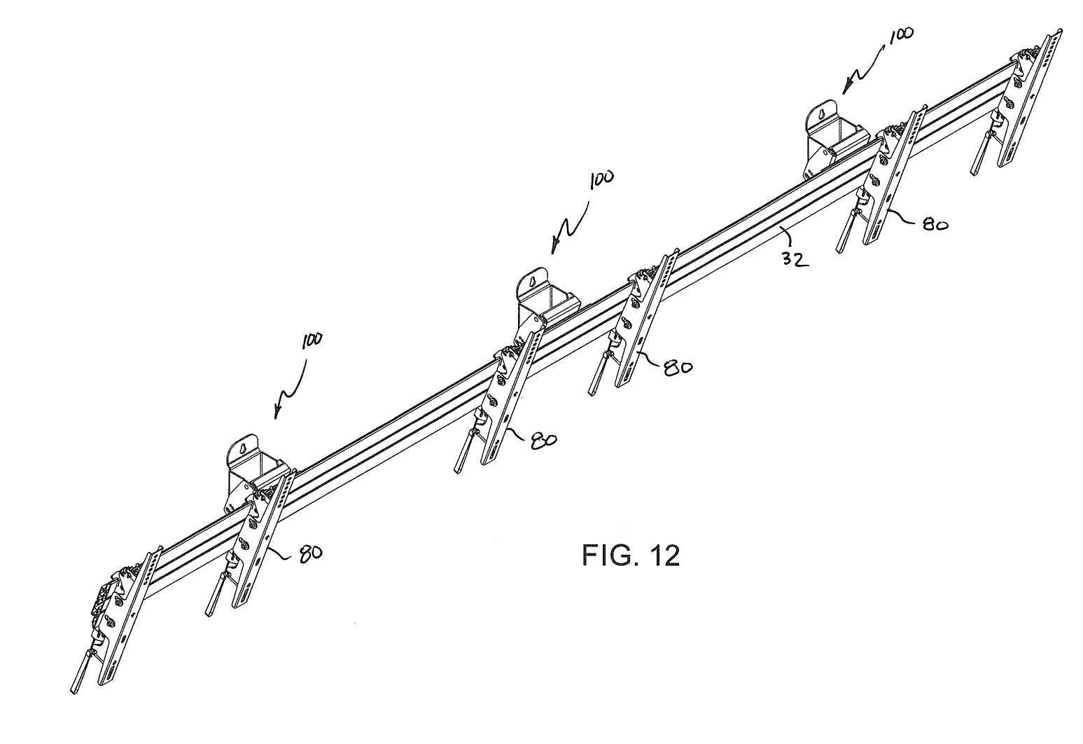

Referring of FIG. 8, an embodiment of the mount 100 is shown that is useful for attaching to a wall 16. In this embodiment many of the features of the mount 100 are similar to the ceiling mount 10 embodiment shown in FIGS. 1-7 and, thus, no detailed discussion is required. The principle difference is that the fixed bracket 18 includes a mounting flange 102 that is attached to the side walls 22. The mounting flange 102 includes holes for securing the fixed bracket 18 to the wall 16. FIG. 9 is a side view of the mount of FIG. 8 illustrating the adjustable bracket 20 in an angular orientation with respect to the fixed bracket 18. FIG. 10 is a side view of the mount of FIG. 8 illustrating a monitor mount 80 attached to the adjustable bracket, with the adjustable bracket 20 disengaged from the fixed bracket 18. FIG. 11 illustrated the adjustable bracket mounted to the fixed bracket. FIG. 12 is a perspective view illustrating multiple wall mounted monitor assemblies 100 attached to a wall for supporting an extrusion with multiple monitor mounts 80.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed. The various embodiments and elements can be interchanged or combined in any suitable manner as necessary.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

1. An adjustable mount for a TV or video monitor, the mount comprising:
a fixed bracket having two side walls that each have a sloped front edge, a top end and a bottom end, a mounting notch is formed in the top end of each of the side walls adjacent to the sloped front edge, the fixed bracket having an axis extending between and parallel to the side walls, and
at least one adjustable bracket removably mounted on the fixed bracket, the adjustable bracket including a front panel with an outer surface lying along a plane, the plane defining an angle relative to the axis of the fixed bracket, two side panels attached to the front panel and extending away from the outer surface, the side panels being spaced apart from one another a sufficient distance and located adjacent to and outside of the side walls of the fixed bracket when the adjustable bracket is mounted to the fixed bracket, and a crossbar extending between and attached to the side panels adjacent to a top end of the side panels, the crossbar seated and rotatable within the notches of the side walls of the fixed bracket, the rotation of the crossbar in the notches causing the adjustable bracket to pivot relative to the fixed bracket so as to vary the angle of the front panel plane relative to the axis of the fixed bracket, the sloping front edges of the fixed bracket side walls facilitating the amount of pivoting.

2. The mount according to claim 1, wherein the side walls of the fixed bracket are connected to one another by a top wall

3. The mount according to claim 1, wherein the side walls of the fixed bracket are attached to a ceiling support.

4. The mount according to claim 2, wherein there are two front sloped edges on opposite sides of each side wall, the front edges sloping downward and inward toward one another, and wherein there are two notches on the top end of each side wall, one notch adjacent to each front edge.

5. The mount according to claim 1, further comprising an extrusion mounted to the front panel of the adjustable bracket.

6. The mount according to claim 1, wherein the angle of the front panel plane is adjustable in a range from about substantially zero degrees to at least about 20 degrees relative to the axis of the fixed bracket.

7. The mount according to claim 1, further comprising a locking mechanism to lock the angular orientation of the adjustable bracket relative to the fixed bracket.

8. The mount according to claim 7, wherein the locking mechanism comprising a curved slot formed in at least one side panel of the adjustable bracket that is aligned with a threaded hole in the side wall of the fixed bracket, and a locking bolt removable inserted through the slot and threaded into the hole.

9. The mount according to claim 7, wherein the locking mechanism is an incremental adjustment mechanism with a series of adjustment holes formed in at least one side panel at predetermined positions so as to provide incremental angular adjustments, a pin hole formed in the side wall of the fixed bracket that is aligned with the adjustment holes, and a removable bolt or pin inserted through one adjustment hole into the pin hole to lock the adjustable bracket in a desired orientation.

10. The mount according to claim 9, wherein the pin is spring loaded and attached to the adjustable bracket, the pin being biased into engagement with the holes to permit easy disengagement by pulling the pin out of engagement with the pin hole.

11. The mount according to claim 9, wherein the adjustment holes are spaced apart from one another a sufficient distance to provide five degree changes in angular orientation of the front panel plane relative to the axis of the fixed bracket.

12. The mount according to claim 1, further comprising an adapter angle attached to the front panel, the adapter angle defining a channel section with spaced apart legs, and an extrusion removably attached to the adapter angle, the extrusion having spaced apart slots that are configured to engage with and slide upon the legs of the adapter angle.

13. The mount according to claim 1, wherein the fixed bracket includes a mounting flange that is located between and attached to the side walls, the mounting flange including one or more holes for securing the fixed bracket to the wall.

14. The mount according to claim 1, wherein there are two front sloped edges on opposite sides of each side wall, the front edges sloping downward and inward toward one another, and wherein there are two notches on the top end of each side wall, one notch adjacent to each front edge.

15. The mount according to claim 14, wherein the angle of the front panel plane is adjustable in a range from about substantially zero degrees to at least about 20 degrees relative to the axis of the fixed bracket.

16. The mount according to claim 15, further comprising a locking mechanism to lock the angular orientation of the adjustable bracket relative to the fixed bracket.

17. The mount according to claim 16, wherein the locking mechanism comprising a curved slot formed in at least one side panel of the adjustable bracket that is aligned with a threaded hole in the side wall of the fixed bracket, and a locking bolt removable inserted through the slot and threaded into the hole.

18. The mount according to claim 16, wherein the locking mechanism is an incremental adjustment mechanism with a series of adjustment holes formed in at least one side panel at predetermined positions so as to provide incremental angular adjustments, a pin hole formed in the side wall of the fixed bracket that is aligned with the adjustment holes, and a removable bolt or pin inserted through one adjustment hole into the pin hole to lock the adjustable bracket in a desired orientation.

19. The mount according to claim 16, wherein the side walls of the fixed bracket are connected to one another by a top wall
